(19) United States
(12) Patent Application Publication
(10) Pub. No.: US 2012/0292670 A1
(43) Pub. Date: Nov. 22, 2012

(54) Post-Silicide Process and Structure For Stressed Liner Integration

(75) Inventors: Ming Cai, Hopewell Junction, NY (US); Ahmet S. Ozcan, Pleasantville, NY (US)

(73) Assignee: INTERNATIONAL BUSINESS MACHINES CORPORATION, Armonk, NY (US)

(21) Appl. No.: 13/108,240

(22) Filed: May 16, 2011

(51) Int. Cl. H01L 21/28; H01L 29/78

(52) U.S. Cl. 257/288; 438/664; 257/E21.158; 257/E29.255

(57) ABSTRACT

A method of fabricating a semiconductor device and a corresponding semiconductor device are provided. The method can include implanting a species into a silicide region, the silicide region contacting a semiconductor region of a substrate. A stressed liner may then be formed overlying the silicide region having the implanted species therein. In a particular example, prior to forming the stressed liner, a step of annealing can be performed within an interval less than one second to elevate at least a portion of the silicide region to a peak temperature ranging from 800 to 950° C. The method may reduce the chance of deterioration in the silicide region, e.g., the risk of void formation, due to processing used to form the stressed liner.

### BACKGROUND OF THE INVENTION

1. Field of the Invention

The present invention relates to semiconductor devices and their manufacture, and more particularly relates to a method and structure of making a field effect transistor having silicided regions, particularly field effect transistors having stressed liners.

2. Description of the Related Art

Field effect transistors (“FETs”) in advanced technologies are semiconductor devices each of which contains a semiconductor region which incorporates a source region, a drain region, and a channel region between the source and drain regions. FETs typically have silicide regions contacting their source and drain regions. The silicide regions, which are more conductive than the source and drain regions, help increase the flow of current through the FET. To increase the performance of the FET, such as the speed at which the FET may switch between on and off states, a stressed dielectric liner may be formed on the silicide regions which applies a stress to the source, drain and the channel regions of such FET.

Silicide regions in FETs typically are formed by depositing a metal onto the source and drain regions and sometimes also the gates of the FETs, and then heating the FET to a temperature such as 400 to 450 degrees Celsius (hereinafter “° C.”) at which the metal reacts with the semiconductor material to form the silicide. Then, the stressed dielectric liner is formed on the silicide regions and other portions of the FETs at a temperature such as 400 to 480° C. The stressed dielectric liner may apply a stress to the semiconductor region of the transistor, i.e., the source, drain and channel regions, which has a magnitude exceeding one gigapascal (hereinafter “GPa”).

In subsequent processing, a relatively thick dielectric layer can be formed covering the FET, and electrically conductive contacts are formed which extend through the thick dielectric layer and contact the silicide regions to electrically connect with the source and drain regions and the gate of the FET.

Further improvements can be provided in the fabrication of FETs having silicide regions and stressed liners.

### SUMMARY OF THE INVENTION

According to an aspect of the invention, a method is provided of fabricating a semiconductor device. Such method includes implanting a species into a silicide region contacting a semiconductor region of a substrate. A stressed liner may then be formed overlying the silicide region having the implanted species therein. According to a particular aspect of the invention, a conductive via can be formed which extends through the stressed liner and is electrically connected with the semiconductor region.

According to a particular aspect, prior to forming the stressed liner, within an interval less than one second, a step of annealing can be performed to elevate at least a portion of the silicide region to a peak temperature ranging from 800 to 950° C. Examples of annealing processes are laser spike annealing and flash annealing, either or both of which may be used. In one example, the interval can be limited to less than 10 milliseconds. In a particular example, the peak temperature can be at least 900° C. and the interval can be less than 10 milliseconds.

In a particular example, the annealing may include at least one of laser spike annealing or flash annealing, the peak temperature may be approximately 950° C. and the annealing can maintain at least a portion of the silicide region at the peak temperature ranging from 0.1 millisecond to 10 milliseconds.

In one example, the implanting step can produce a distribution of the implanted species centered at a depth within the silicide region which is less than a depth at which the silicide regions contact the semiconductor region. In a particular example, the centered depth may be less than or equal to a depth at a midpoint of the thickness of the silicide region above the semiconductor region.

The implanted species can include at least one of carbon, nitrogen, boron, boron fluoride or arsenic. The implanting step can be performed at an energy between about 0.2 keV and 10 keV. A typical dose of the implanted species can be between 5×10¹⁴cm⁻² and 5×10¹⁵cm⁻².

The stressed liner typically has a stress greater than one gigapascal (GPa) in magnitude, and the silicide region typically consists essentially of a silicide of at least one of nickel, platinum, or palladium.

A method of fabricating a semiconductor device according to a particular aspect of the invention may include: implanting a species of at least one of carbon, nitrogen, boron, boron fluoride or arsenic at a dose between about 5×10¹⁴cm⁻² and about 5×10¹⁵cm⁻² into a silicide region, the silicide region contacting a semiconductor region of a substrate, to produce a distribution of the implanted species centered at a depth within the silicide region which is less than a depth at which the silicide region contacts the semiconductor region. The silicide region may consist essentially of a silicide of at least one of nickel, platinum, or palladium Annealing may be performed within an interval of less than one second to elevate at least a portion of the silicide region to a peak temperature between 800 and 950° C. After the annealing, a stressed liner can be formed which has a stress of at least one gigapascal in magnitude overlying the at least a portion of the silicide region having the implanted species therein.

In a particular aspect of the invention, a conductive via can be formed which extends through the stressed liner and is electrically connected with the semiconductor region.

A semiconductor device according to an aspect of the invention can include: a semiconductor region of a substrate having a first portion having a first conductivity type and second portions extending from edges of the first portion and having a second conductivity type opposite the first conductivity type, the first and second portions having major surfaces. A gate may overlie the major surface of the first portion of the semiconductor region. A silicide region may overlie and contact the major surfaces of the second portions of the semiconductor region. The silicide region may contain at least one implanted species selected from the group consisting of carbon, nitrogen, boron, boron fluoride and arsenic having a distribution centered at a depth within the silicide region which is less than depths of the major surfaces of the second portions of the semiconductor region. The silicide region may consist essentially of a silicide of at least one of nickel, platinum, or palladium. Dielectric spacers may separate the gate from the silicide region, and a stressed liner may overlie the silicide region having the implanted species therein. The dielectric spacers may have the at least one implanted species therein, the implanted species having a distribution centered at a particular depth internally within the dielectric material of the dielectric spacers.

In a particular aspect of the invention, a plurality of conductive vias may extend through the stressed liner and be electrically connected with the semiconductor region. A silicide region may overlie and be electrically connected with the gate, and a conductive via may extend through the stressed liner and be electrically connected with of the silicide region overlying the gate.

### BRIEF DESCRIPTION OF THE DRAWINGS

FIG. 1 is a flow diagram illustrating steps in a process of fabricating a transistor according to a first embodiment of the invention.

FIG. 2 is a flow diagram illustrating steps in a process of fabricating a transistor according to a second embodiment of the invention.

FIG. 3 is a sectional view illustrating a transistor undergoing a step of implanting a species therein in a fabrication process according to an embodiment of the invention.

FIG. 4 is a sectional view illustrating structure of a transistor according to a particular embodiment of the invention.

FIG. 5 is a sectional view illustrating structure of a transistor according to another embodiment of the invention.

### DETAILED DESCRIPTION

Advanced semiconductor chips typically incorporate very large numbers, e.g., billions, of semiconductor devices such as FETs. To fabricate semiconductor chips which operate reliably throughout their intended lifetimes, the incidence of failure in each chip must be reduced to an extent in which no more than a few isolated device failures is likely to occur during the entire lifetime of the chip.

In FETs that have silicide regions and stressed dielectric liners, the inventors recognize that the process of forming the stressed liner can negatively affect the silicide regions. The formation of a stressed liner at temperatures, e.g., 500° C. or above, which is above a temperature, e.g., 400 to 450° C. at which the silicide regions are formed, can cause the silicide region to develop voids in which the silicide region has insufficient coverage or insufficient thickness in certain areas on the surface of the source region and the drain region. Voids in the silicide regions can increase electrical resistance of the silicide regions, and may in some cases cause the later formed conductive contacts to fail, or may cause electrical circuits which incorporate FETs to fail.

The inventors recognize that voids in the silicide regions may pose even greater risks to FET performance as the size of FETs shrinks further in future generations and the voids may occupy a proportionally greater area of the silicide regions. The techniques and structures described herein may help to reduce the risk that voids may form in silicide regions of FETs having stressed dielectric liners, or may help to reduce the size of voids which can form.

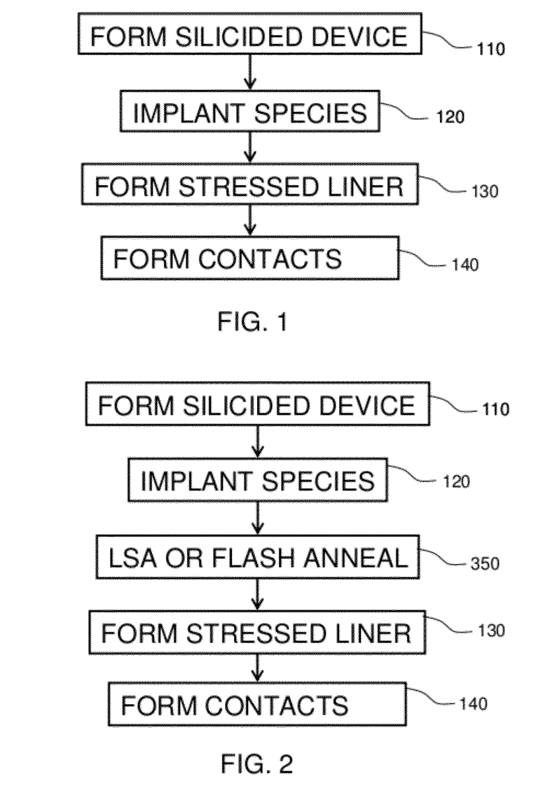

Accordingly, FIG. 1 illustrates steps in a method of fabricating a semiconductor device according to an embodiment of the invention. As seen in FIG. 1, step 110 refers to forming a silicided device. The silicided device can be a FET such as described in the foregoing or can be another type of device over which a stressed liner may be formed. In one example, such silicided device can be a FET as described above which has source and drain regions on which silicide regions are formed by a “self-aligned” silicide process, commonly referred to as a “salicide” process. The gate of such FET may also be silicided. Some examples of silicides which may be provided in the semiconductor device include a silicide of at least one of nickel, platinum or palladium. For example, the silicide region can include nickel silicide. In another example, the silicide region can include a silicide of nickel and platinum, or a silicide of nickel and palladium. In such examples, the percentage of platinum in a silicide of nickel and platinum typically ranges between 5 and 20%, or the percentage of platinum in a silicide of nickel and palladium typically ranges between 5 and 20%.

In one example, a silicided FET can be a FET such as made according to an advanced semiconductor technology in which the length of the channel region of the transistor is less than 50 nanometers, and may be quite smaller. At such dimension, the widths, i.e., the smallest dimensions of the source region and the drain region in a direction along their surfaces in contact with the silicide regions may in one example range from a few tens of nanometers to a few hundred nanometers. At these dimensions, silicide regions which have voids greater than a few nanometers in width could significantly impact the performance of at least some FETs on an integrated circuit, and can cause the incidence of device failures on the semiconductor chip to increase beyond the established tolerable limit. Processing as further described below may reduce the width of or number of voids in the silicide regions of silicided devices such as FETs which have stressed liners thereon.

According to the embodiment shown in FIG. 1, step 120 refers to implanting a species into the silicide regions of the device. Typically, this step is performed as a blanket implant into one or more exposed areas on a semiconductor wafer in which semiconductor devices are disposed. As typically performed, the species is implanted into all regions of each semiconductor device being implanted. However, a mask may be used to confine the implanted species to only particular areas of a wafer in which the devices to be implanted are disposed.

Examples of species that can be implanted include carbon, nitrogen, boron, boron fluoride, and arsenic. Carbon or nitrogen species do not alter the conductivity type (p-type or n-type) of the semiconductor region that the species reaches during the implanting step. Either carbon, nitrogen, or both carbon and nitrogen can be implanted into silicide regions contacting underlying semiconductor regions which have either p-type or n-type conductivity. However, other species such as boron, boron fluoride and arsenic are commonly used as dopants in creating p-type semiconductor regions in the case of boron, and in creating n-type semiconductor regions in the case of arsenic. Therefore, boron, or boron fluoride are each a species which can be selectively implanted into silicide regions which contact underlying p-type conductivity regions, and arsenic is a species which can be selectively implanted into silicide regions which contact underlying n-type conductivity regions. In a particular embodiment, a mask such as a photoresist mask can be used during the implanting process to limit the implanting of a dopant material such as boron or boron fluoride to semiconductor devices such as PFETs which have silicide regions contacting underlying semiconductor regions of p-type conductivity. Similarly, a mask such as a photoresist mask can be used during the implanting process to limit the implanting of a dopant material such as arsenic to semiconductor devices such as NFETs which have silicide regions contacting underlying semiconductor regions of n-type conductivity.

FIG. 3 illustrates a semiconductor device such as a FET 200 in a corresponding stage of processing in which a species is being implanted into silicide regions 210 contacting a source region 212, a drain region 214 thereof. When the semiconductor device or FET includes a gate 222 having a silicide region 220 thereon, this step may also implant a species into the silicide region 220. As shown in FIG. 3, the FET 200 typically includes dielectric spacers 232, 234 between the gate 222 and the source and drain regions 212, 214 thereof. FIG. 3 depicts one possible implementation among a very large number of possible implementations. The shape of, particular configuration of, and even the number of dielectric spacers between the gate 222 and each source region 212 or each drain region 214 can vary depending upon the design and function of the semiconductor device.

In an example, the implant can be performed at an energy between 0.2 kilo-electron-volts (“keV”) and 10 keV. In one example, the dose of the implanted species can be between 5×10¹⁴cm⁻² and 5×10¹⁵cm⁻². As shown in FIG. 3, the implant can be performed so as to control the depth at which the implanted species is centered within the silicide regions. The depth at which the implant is centered typically is less than a depth at which the silicide regions 210 contact major surfaces 236 of underlying semiconductor regions such as the source region 212 and the drain region 214. When the semiconductor device includes a silicide region 220 contacting the gate 222, and the implanting step 120 implants a species into the silicide region 220, the same relationship can also apply as to the depth at which the implanted species is centered within silicide region 220.

In a particular example, the depth at which the implant is centered within the silicide region 210 can be less than or equal to a depth at a midpoint of the thickness 224 of the silicide regions 210 in a direction perpendicular to the major surfaces 236 of the source and drain regions 212, 214 in contact therewith. The same relationship can apply to the depth at which the implant is centered within the silicide region 220, as less than or equal to a depth at a midpoint of the thickness 226 of the silicide region 220 in a direction perpendicular to the surfaces of the source and drain regions 212, 214 in contact therewith. Typical thicknesses of the silicide regions 210 (and the silicide region 220 when present) are from a few nanometers to a few tens of nanometers.

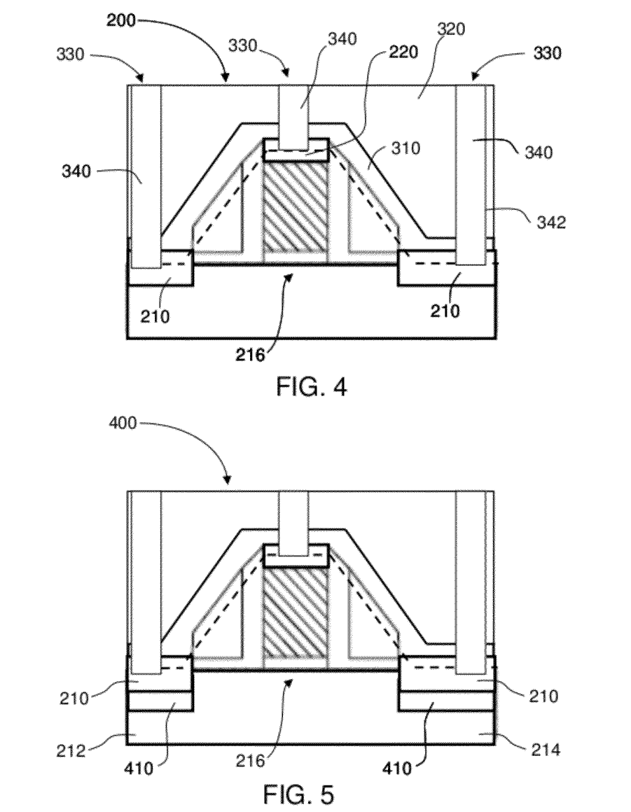

As seen in FIG. 3, the blanket implant results in the species being implanted into areas of the device other than the silicide regions. As particularly shown in FIG. 3, the implanting step typically also implants the species into the dielectric spacers 232, 234 disposed between the gate and the source and drain regions 212, 214 of each FET. The species typically is implanted into the dielectric spacers to depths close or equal to the depth of implant in the silicide regions. Thus, in the completed semiconductor device 200 such as shown in FIG. 4, the implanted species typically will be present at such depth in the dielectric spacers, thereby functioning as a signature that such blanket implant has been performed after fabricating the semiconductor devices including the silicide regions and dielectric spacers thereof.

As further shown in FIG. 3, a layer 230 of material such as a “screen oxide” or other material can be present atop the underlying structure including the silicide regions 210 or 220. Layer 230 can assist during the implanting process in centering the implanted species at an intended depth. Such layer 230, if present typically has a thickness of 30 to 40 angstroms and typically is formed by chemical vapor deposition as a layer blanketing the entire area of a semiconductor wafer. After implanting the species into the silicide regions, layer 230 can be left in place for subsequent processing, or removed as needed before proceeding to subsequent processing.

Referring again to FIG. 1, in step 130 the method can further include forming a stressed liner after implanting the species into the silicided semiconductor device. The stressed liner typically is made of silicon nitride and has an internal stress of magnitude greater than 1.0 gigapascals (“GPa”) which is either compressive or tensile. The magnitude and type of the internal stress (compressive or tensile) can be determined by selecting appropriate parameters of the process used to form the stressed liner, typically by deposition onto exposed surfaces of the FET. In one example, when the semiconductor device is a p-type FET or (“PFET”), the source and drain regions 212, 214 thereof have p-type conductivity, a stressed liner having compressive stress can be formed atop the source and drain regions of the PFET. In such case, the compressive stressed liner can apply a compressive stress to the channel region of the PFET which improves the performance of the PFET. The value of the compressive stress typically has a magnitude greater than 1.0 gigapascals (“GPa”). In a particular example, the compressive stress can have a value such as −3.5 GPa. FIG. 4 illustrates an example of a FET 200 having a stressed liner 310 covering the silicide regions 210 (and 220 when present) and other portions of the FET. When the FET 200 is a PFET, the stressed liner 310 can have compressive stress for applying a compressive stress to a channel region 216 of the FET.

Alternatively, when the semiconductor device is an n-type FET or (“NFET”), the source and drain regions 212, 214 thereof can have n-type conductivity, and a stressed liner having tensile stress can be formed atop the source and drain regions. In such case, the tensile stressed liner can apply a tensile stress to the channel region of the NFET which improves the performance of the NFET. The value of the tensile stress typically has a magnitude greater than 1.0 gigapascals (“GPa”). In a particular example, the tensile stress can have a value such as 1.7 GPa.

After the forming (130) of the stressed liner, in further processing can include forming conductive contacts (140) such as conductive vias which electrically connect the source and drain regions and gate of the FET to other circuitry (not shown) of the semiconductor chip. For example, as seen in FIG. 4, a relatively thick dielectric region 320 can be formed overlying the stressed liner 310. The dielectric region 320 typically consists essentially of an oxide. In one example, the dielectric region can be formed by a high density plasma (“HDP”) deposition technique. The dielectric region 320 can in some cases be formed by a self-planarizing process, or alternatively, be deposited and a major surface thereof be planarized after deposition by polishing, such as by a chemical- mechanical-polishing (“CMP”) process, for example. The conductive contacts then can be formed by forming openings 330 extending through the dielectric region 320 which expose the underlying silicide regions 210 or 220 or both. In one example, the openings can be formed by etching the dielectric region selectively relative to the underlying stressed liner (typically of silicon nitride material) such that the etching process stops after exposing portions of the silicon nitride liner 310. Thereafter, the etching process can be varied so as to etch the stressed liner 310 selectively relative to an underlying screen oxide layer 230 (FIG. 3) such that the etching process stops after exposing portions of the underlying screen oxide 230. Subsequently, the etching process can be varied again to etch the screen oxide layer 230 selectively relative to the silicide regions 210 (and 220 if present) and stopping the etching process after exposing portions of the underlying silicide regions 210 (and 220 if present).

Thereafter, columns of conductive material are formed within the openings to form the conductive vias or contacts 340. The conductive material typically includes a metal, a conductive compound of a metal or both. In particular examples, the conductive material can be formed by first depositing an adhesion layer or possibly a conductive barrier layer containing titanium adjacent walls 342 of the openings, after which a second conductive material can be deposited. The second conductive material can include one or more of tungsten, cobalt, phosphorus or a combination thereof, among other possible materials or combinations of materials. With this step, the semiconductor device structure is completed, and subsequent processing can be applied to electrically interconnect the conductive contacts 340 with other conductive structure (not shown) such as horizontally extending metal wiring lines and metal vias which vertically interconnect metal wiring lines at different levels of the chip.

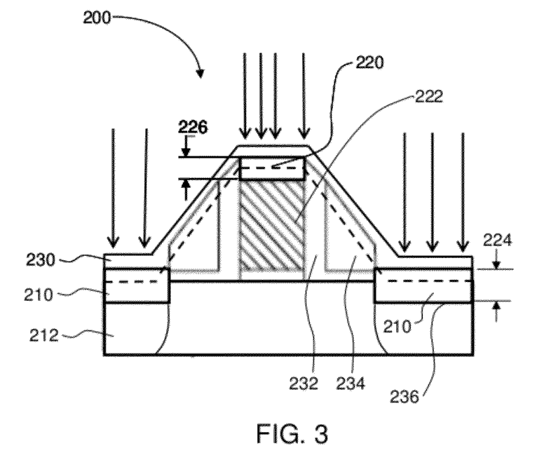

FIG. 2 is a flow chart illustrating an embodiment according to a variation of the process shown and described above with reference to FIG. 1. In this embodiment, a step of annealing 350 involving a very short duration anneal such as a laser spike anneal (“LSA”) or flash anneal is inserted in the process between the steps of implanting 120 a species and forming 130 a stressed liner. The anneal process 350 may help to distribute the implanted species in a way that reduces the final electrical resistance of the silicide regions 210 or the source and drain regions 212, 214. Performing the anneal in a very short interval of time may help to distribute the implanted species within the silicide regions while keeping the distribution of the implanted species essentially within the silicide regions so that the implanted species may not have a significant detrimental impact to the resistance of the source and drain regions or other performance characteristic of the semiconductor devices.

In a particular example, the very short duration anneal can elevate the annealed areas to a peak temperature from 800 to 950° C. within an interval of less than one second. Typically the peak temperature is at least 900° C. and the interval is less than 10 milliseconds. In a particular example, the short duration anneal reaches a peak temperature of approximately 950° C. within at least portions of the silicide regions of the semiconductor devices and maintains the peak temperature therein for an interval ranging from 0.1 to 10 milliseconds.

After the short duration anneal, processing can continue with forming a stressed liner (130) and subsequently forming conductive contacts (140) to the semiconductor devices, as described above relative to FIG. 1.

FIG. 5 depicts a completed FET 400 according to another embodiment in which stressed semiconductor regions 410 may be provided within areas of the source and drain regions 212, 214 of the FET. The stressed semiconductor regions can help to apply a compressive stress or a tensile stress of a particular magnitude (e.g., greater than 1.0 GPa) to the channel region 216 of the FET. In appropriate cases, the stressed semiconductor regions can operate in tandem with the stressed liner to apply stress of a particular type (compressive or tensile) and magnitude to the channel region 216 of the FET.

In one example, when the channel region of the FET consists essentially of silicon, the stressed semiconductor regions may include an alloy of silicon with another semiconductor material. Typically, when the semiconductor device is an PFET, the stressed semiconductor regions may include a compressive stressed alloy of silicon such as silicon germanium, which can be formed within the source and drain regions by epitaxial growth of the stressed semiconductor region. In another typical example, when the semiconductor device is an NFET, the stressed semiconductor regions may include a tensile stressed alloy of silicon such as silicon carbon. However, it is possible for tensile stressed semiconductor regions to be provided in device regions of PFETs or for compressive stressed semiconductor regions to be provided in device regions of NFETs, such as, for example, in integrated circuits in which only one type of stressed semiconductor region may be provided.

The stressed semiconductor regions 410 can underlie the silicide regions 210. For example, as particularly shown in FIG. 5, the stressed semiconductor regions 410 may overlie and contact other portions of the source and drain regions 212, 214 which consist essentially of silicon, and the silicide regions 210 may overlie and contact the stressed semiconductor regions.

The above description sets forth a variety of materials and process conditions which can be used in carrying out a method of fabricating a semiconductor device according to various embodiments of the invention. In a particular example of a process according to the embodiment of FIG. 2, semiconductor devices having nickel silicide regions on at least source and drain regions thereof are formed on a wafer such as by techniques, e.g., a salicide process, as described above, for example. Silicide regions may also be formed atop the gates in particular cases. An optional screen oxide having a thickness of 30 to 50 angstroms, for example, then can be blanket deposited on the wafer thus covering the silicide regions. Carbon then can be blanket implanted into the wafer to a depth typically less than or equal to a thickness of the silicide regions, for example, at an energy between 0.2 keV and 10 keV and at a dose ranging from 5×10¹⁴ cm⁻² and 5×10¹⁵cm⁻². A very short duration anneal such as a laser spike anneal or a flash anneal then can be performed (350) which elevates the annealed areas to a peak temperature within an interval of up to 10 milliseconds. In an example, the peak temperature reached within the silicide regions can be from 800 to 950° C. In a particular example, the short duration anneal reaches a peak temperature of approximately 950° C. within at least portions of the silicide regions of the semiconductor devices and maintains the peak temperature therein for an interval ranging from 0.1 to 10 milliseconds. Thereafter, a stressed liner such as a silicon nitride liner can be formed (130) atop the semiconductor devices for applying a stress to the semiconductor devices at a magnitude of 1.0 GPa or greater. This step can involve the deposition of compressive and tensile stressed liners atop PFET and NFET devices, respectively. A stressed liner may typically have a compressive stress having a magnitude of about 3.5 GPa atop the silicide regions of PFETs on the wafer. Another stressed liner may typically have a tensile stress having a magnitude of about 1.7 GPa atop the silicide regions of NFETs on the wafer. Thereafter, a dielectric region and conductive contacts are formed which extend through the dielectric region and electrically connect with the source and drain regions and the gates of the semiconductor devices, e.g., directly or through the silicide regions thereon.

While the invention has been described in accordance with certain preferred embodiments thereof, those skilled in the art will understand the many modifications and enhancements which can be made thereto without departing from the true scope and spirit of the invention, which is limited only by the claims appended below.

What is claimed is:

1. A method of fabricating a semiconductor device, comprising:
implanting a species into a silicide region, the silicide region contacting a semiconductor region of a substrate; and
forming a stressed liner overlying the silicide region having the implanted species therein.

2. The method as claimed in claim 1, further comprising forming a conductive via extending through the stressed liner and electrically connected with the semiconductor region.

3. The method as claimed in claim 1, further comprising:
prior to forming the stressed liner, within an interval less than one second annealing to elevate at least a portion of the silicide region to a peak temperature ranging from 800 to 950° C.

4. The method as claimed in claim 3, wherein the peak temperature is at least 900° C. and the interval is less than 10 milliseconds.

5. The method as claimed in claim 3, wherein the annealing includes at least one of laser spike annealing or flash annealing.

6. The method as claimed in claim 3, wherein the annealing includes at least one of laser spike annealing or flash annealing, the peak temperature is approximately 950° C. and the annealing maintains the at least a portion of the silicide region at the peak temperature ranging from 0.1 millisecond to 10 milliseconds.

7. The method as claimed in claim 1, wherein the implanting produces a distribution of the implanted species centered at a depth within the silicide region which is less than a depth at which the silicide regions contact the semiconductor region.

8. The method as claimed in claim 7, wherein the centered depth is less than or equal to a depth at a midpoint of the thickness of the silicide region above the semiconductor region.

9. The method as clamed in claim 7, wherein the implanted species includes at least one of carbon, nitrogen, boron, boron fluoride or arsenic.

10. The method as claimed in claim 9, wherein the implanting step is performed at an energy between about 0.2 keV and 10 keV.

11. The method as claimed in claim 10, wherein a dose of the implanted species is between 5×10¹⁴cm⁻² and 5×10¹⁵cm⁻².

12. The method as claimed in claim 9, wherein the stressed liner has a stress greater than one gigapascal (GPa) in magnitude.

13. The method as claimed in claim 12, wherein the silicide region consists essentially of a silicide of at least one of nickel, platinum, or palladium.

14. A method of fabricating a semiconductor device, comprising:
implanting a species of at least one of carbon, nitrogen, boron, boron fluoride or arsenic at a dose between about 5×10¹⁴cm⁻² and about 5×10¹⁵cm⁻²into a silicide region contacting a semiconductor region of a substrate to produce a distribution of the implanted species centered at a depth within the silicide region which is less than a depth at which the silicide region contacts the semiconductor region, the silicide region consisting essentially of a silicide of at least one of nickel, platinum, or palladium;
annealing, within an interval of less than one second, to elevate at least a portion of the silicide region to a peak temperature between 800 and 950° C.; and
after the annealing, forming a stressed liner having a stress of at least one gigapascal in magnitude overlying the at least a portion of the silicide region having the implanted species therein.

15. A semiconductor device, comprising:
a semiconductor region of a substrate having a first portion having a first conductivity type and second portions extending from edges of the first portion and having a second conductivity type opposite the first conductivity type, the first and second portions having major surfaces;
a gate overlying the major surface of the first portion of the semiconductor region;
a silicide region overlying and contacting the major surfaces of the second portions of the semiconductor region, the silicide region having at least one implanted species therein selected from the group consisting of carbon, nitrogen, boron, boron fluoride and arsenic, the implanted species having a distribution centered at a depth within the silicide region which is less than depths of the major surfaces of the second portions of the semiconductor region, the silicide region consisting essentially of a silicide of at least one of nickel, platinum, or palladium;
dielectric spacers separating the gate from the silicide region; and
a stressed liner overlying the silicide region having the implanted species therein,
wherein the dielectric spacers have the at least one implanted species therein, the implanted species having a distribution centered at a particular depth internally within the dielectric material of the dielectric spacers.

16. The semiconductor device of claim 15, wherein the silicide overlies and contacts a major surface of the gate, the device further comprising conductive vias extending through the stressed liner and electrically connected with the gate and the second portions of the semiconductor region.

17. The semiconductor device of claim 15, wherein the semiconductor region has p-type conductivity and the silicide region and dielectric spacers include at least one of carbon, nitrogen, boron, or boron fluoride, and the stressed liner has a stress greater than 3.5 gigapascals (GPa) in magnitude.

18. The semiconductor device of claim 17, wherein the semiconductor region includes an alloy of silicon with germanium.

19. The semiconductor device of claim 15, wherein the semiconductor region has n-type conductivity and the silicide region and dielectric spacers include at least one of carbon, nitrogen, or arsenic, and the stressed liner has a stress greater than 1.0 gigapascals (GPa) in magnitude.

20. The semiconductor device of claim 19, wherein the semiconductor region includes an alloy of silicon with carbon.
